(19) United States
(12) Patent Application Publication
(10) Pub. No.: US 2013/0160812 A1
(43) Pub. Date: Jun. 27, 2013

(54) BACK CONTACT PHOTOVOLTAIC MODULE WITH INTEGRATED GLASS BACK-SHEET

(71) Applicant: E I DU PONT DE NEMOURS AND COMPANY, Wilmington, DE (US)

(72) Inventors: WILLIAM J. BORLAND, Chapel Hill, NC (US); Thomas D. Lantzer, Wake Forest, NC (US)

(73) Assignee: E I DU PONT DE NEMOURS AND COMPANY, Wilmington, DE (US)

(21) Appl. No.: 13/723,632

(22) Filed: Dec. 21, 2012

Related U.S. Application Data
(60) Provisional application No. 61/579,024, filed on Dec. 22, 2011.

(51) Int. Cl. H01L 31/05; H01L 31/18

(52) U.S. Cl. CPC H01L 31/0516; H01L 31/18
USPC 136/244; 438/66

(57) ABSTRACT

A back-contact solar cell module comprises an array of back-contact solar cells having a substantially common coefficient of thermal expansion and a glass back-sheet having a coefficient of thermal expansion that is within 15% of the coefficient of thermal expansion of the solar cells of the solar cell array. The glass back-sheet has at least two conductive circuits formed of sintered metal and glass on a surface of the glass back-sheet. Electrical contacts on the back side of the solar cells of the solar cell array are physically and electrically connected to the conductive circuits formed on the glass back-sheet. Processes for making such back-contact solar cell modules are also provided.

### FIELD OF THE INVENTION

The present invention relates to back-contact photovoltaic modules with conductive circuitry integrated into the back-sheets, and to processes for making such photovoltaic modules with integrated back-sheets.

### BACKGROUND

A photovoltaic cell converts radiant energy, such as sunlight, into electrical energy. In practice, multiple photovoltaic cells are electrically connected together in series or in parallel and are protected within a photovoltaic module or solar module.

As shown in FIG. 1, a photovoltaic module 10 typically comprises a light-transmitting front sheet substrate 12, a front encapsulant layer 14, an active photovoltaic cell layer 16, a rear encapsulant layer 18 and a back-sheet 20. The light-transmitting front sheet substrate may be comprised of glass or plastic, such as, polycarbonate, acrylic, polyacrylate, cyclic polyolefin, polystyrene, polyamide, polyester, silicon polymers and copolymers, fluoropolymers and the like, and combinations thereof. The front and back encapsulant layers 14 and 18 adhere the photovoltaic cell layer 16 to the front and back sheets, they seal and protect the photovoltaic cells from moisture and air, and they protect the photovoltaic cells against physical damage. The encapsulant layers 14 and 18 are typically comprised of a thermoplastic or thermosetting resin such as ethylene-vinyl acetate copolymer (EVA). The photovoltaic cell layer 16 is made up of any type of photovoltaic cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The module layers need to remain intact and adhered for the service life of the photovoltaic module, which may extend for multiple decades.

The photovoltaic cells typically have electrical contacts on both the front and back sides of the photovoltaic cells. However, contacts on the front sunlight receiving side of the photovoltaic cells can cause up to a 10% shading loss.

In back-contact photovoltaic cells, all of the electrical contacts are moved to the back side of the photovoltaic cell. With both the positive and negative polarity electrical contacts on the back side of the photovoltaic cells, electrical circuitry is needed to provide electrical connections to the positive and negative polarity electrical contacts on the back of the photovoltaic cells. U.S. Patent Application No. 2011/0067751 discloses a back contact photovoltaic module with a back-sheet having patterned electrical circuitry that connects to the back contacts on the photovoltaic cells during lamination of the solar module. The circuitry is formed from a metal foil that is adhesively bonded to a carrier material such as polyester film or Kapton® film. The carrier material may be adhesively bonded to a protective layer such as a Tedlar® fluoropolymer film. The foil is patterned using etching resists that are patterned on the foil by photolithography or by screen printing according to techniques used in the flexible circuitry industry. The back contacts on the photovoltaic cells are adhered to and electrically connected to the foil circuits by an adhesive conductive paste.

There is a need for alternative back-contact photovoltaic modules in which conductive circuitry is integrated into a rigid back-sheet. There is also a need for moisture impermeable back-sheets that maintain moisture integrity for the long service life of the photovoltaic modules which may extend for decades. There is also a need for photovoltaic back contact modules in which the back contacts securely attach to the back-sheet circuitry and remain securely attached for multiple decades.

### BRIEF DESCRIPTION OF THE DRAWINGS

The detailed description will refer to the following drawings which are not drawn to scale and wherein like numerals refer to like elements:

FIG. 1 is cross-sectional view of a conventional solar cell module.

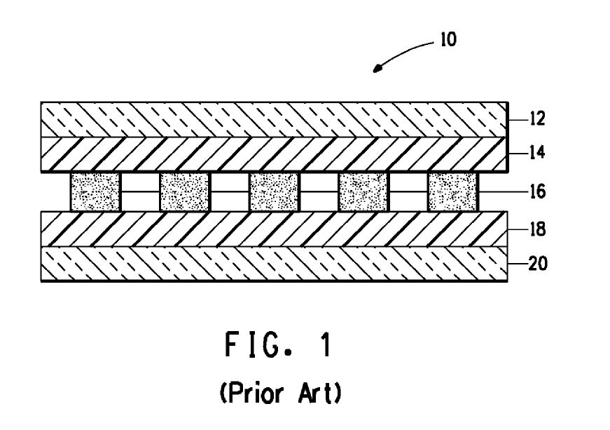

FIGS. 2a and 2b are schematic plan views of the back side of arrays of back-contact solar cells.

FIGS. 3a and 3b are perspective views of glass back-sheets with integrated electrically conductive circuitry.

FIG. 4 is a plan view of a an interlayer dielectric (ILD) layer.

FIGS. 5a and 5b are cross-sectional views illustrating one disclosed process for forming a back-contact solar cell module in which conductive circuitry on a glass back-sheet is electrically connected to the back contacts of solar cells.

### SUMMARY

A photovoltaic module with a glass back-sheet is provided. The module comprises a solar cell array of at least four solar cells in which each of the solar cells have a front light receiving side and an opposite back side, and in which the back side of each of said solar cells have positive and negative polarity electrical contacts thereon. The solar cells of the solar cell array have a substantially common coefficient of thermal expansion. The glass back-sheet has a first surface facing the back side of the solar cells of the solar cell array and an opposite second surface. The glass back sheet has a coefficient of thermal expansion that is within 15% of the coefficient of thermal expansion of the solar cells of the solar cell array. The glass back-sheet has at least two conductive circuits on its first surface that are comprised of sintered metal and an inorganic binder. The conductive circuits are physically and electrically connected to the electrical contacts on the back side of the solar cells of the solar cell array. A process for making such photovoltaic modules is also provided.

### DETAILED DESCRIPTION OF THE INVENTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

As used herein, the terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

As used herein, the terms “sheet”, “layer” and “film” are used in their broad sense interchangeably. A “front sheet” is a sheet, layer or film on the side of a photovoltaic module that faces a light source and may also be described as an incident layer. Because of its location, it is generally desirable that the front sheet has high transparency to the incident light. A “back-sheet” is a sheet, layer or film on the side of a photovoltaic module that faces away from a light source, and is generally opaque. In some instances, it may be desirable to receive light from both sides of a device (e.g., a bifacial device), in which case a module may have transparent layers on both sides of the device.

As used herein, “encapsulant” layers are used to encase the fragile voltage-generating photoactive layer, to protect it from environmental or physical damage, and hold it in place in the photovoltaic module. Encapsulant layers may be positioned between the solar cell layer and the front incident layer, between the solar cell layer and the back-sheet, or both. Suitable polymer materials for the encapsulant layers typically possess a combination of characteristics such as high transparency, high impact resistance, high penetration resistance, high moisture resistance, good ultraviolet (UV) light resistance, good long term thermal stability, good long term weatherability, and adequate adhesion strength to frontsheets, back-sheets, other rigid polymeric sheets and solar cell surfaces.

As used herein, “inter layer dielectric” (ILD) is a layer of a low dielectric constant k material used to electrically separate closely spaced electrically conductive layers or lines arranged in several levels of an electrical circuit or device such as a photovoltaic module.

As used herein, the terms “photoactive” and “photovoltaic” may be used interchangeably and refer to the property of converting radiant energy (e.g., light) into electric energy. As used herein, the terms “photovoltaic cell” or “photoactive cell” or “solar cell” mean an electronic device that converts radiant energy (e.g., light) into an electrical signal. A photovoltaic cell includes a photoactive material layer that may be an organic or inorganic semiconductor material that is capable of absorbing radiant energy and converting it into electrical energy. The terms “photovoltaic cell” or “photoactive cell” or “solar cell” are used herein to include photovoltaic cells with any types of photoactive layers including, crystalline silicon, polycrystalline silicon, microcrystalline silicon, and amorphous silicon-based solar cells, copper indium (gallium) diselenide solar cells, cadmium telluride solar cells, compound semiconductor solar cells, dye sensitized solar cells, and the like.

As used herein, the term “back-contact solar cell” means a solar cell having both positive and negative polarity contacts located on its back side, including metal wrap through (MWT), metal wrap around (MWA), emitter wrap through (EWT), emitter wrap around (EWA), and interdigitated back contact (IBC) solar cells.

As used herein, the term “photovoltaic module” or “solar module” (also “module” for short) means an electronic device having at least one photovoltaic cell protected on one side by a light transmitting front sheet and protected on the opposite side by an electrically insulating protective back-sheet.

Disclosed herein are back-contact solar cell modules and processes for forming such modules with rigid glass back-sheets. Also disclosed are processes for forming such back-contact solar modules with integrated conductive circuitry. Each of the solar cells are preferably silicon-based solar cells such as crystalline silicon, polycrystalline silicon, microcrystalline silicon, or amorphous silicon-based solar cells. Each of the solar cells has positive and negative polarity contacts on the back side of the solar cells.

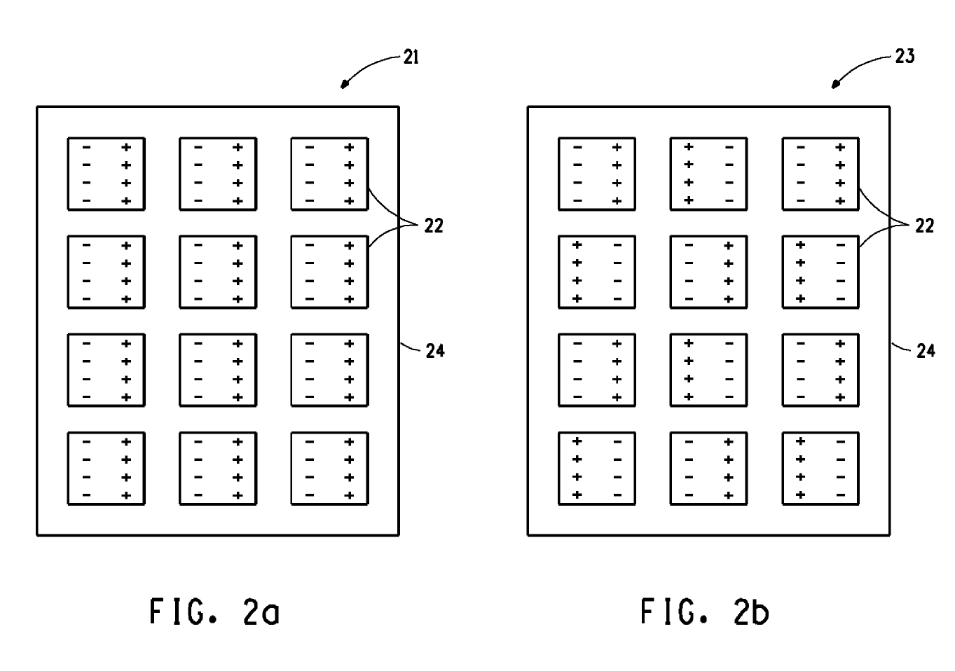

Arrays of back-contact solar cells are shown schematically in FIGS. 2a and 2b. The disclosed integrated glass back-sheet electrically connects back-contact solar cell arrays like those shown in FIGS. 2a and 2b as well as other types of arrays of back-contact solar cells. The solar cell array 21 shown in FIG. 2a includes multiple silicon-based solar cells 22, such as single crystal silicon solar cells. The front side (not shown) of each solar cell 22 is adhered to an encapsulant layer 24 that is or will later be adhered to a transparent front sheet (not shown) of a solar module. Solar modules with an array of twelve solar cells 22 are shown in FIGS. 2a and 2b, but the disclosed back-contact solar modules may have solar cell arrays of anywhere from four to more than 100 solar cells.

Each of the solar cells 22 has multiple positive and negative polarity contacts on back side of the solar cell. The contacts on the back side of the solar cells are typically made of a metal to which electric contacts can be readily formed, such as silver or platinum contact pads. The contacts are typically formed from a conductive paste comprising an organic medium, glass frit and silver particles, and optionally inorganic additives, which are fired at high temperature to form metal contact pads. The solar cells shown in FIGS. 2a and 2b each have a column of four negative contacts and a column of four positive contacts, but it is contemplated that the solar cells could have multiple columns of negative and positive contacts and that each column could have anywhere form two to more than twenty contacts. In the solar cell array shown in FIG. 2a, the contacts of each cell are arranged in the same way. However, it is contemplated that the contacts could be arranged in a variety of ways depending upon the pattern of the conductive electric circuit on the glass back-sheet.

The arrangement shown in FIG. 2a is typically used when the solar cells of the module are connected in parallel. Alternatively, the solar cells in each column of the array can be arranged such that the alternating cells in each column are rotated 180 degrees as shown in FIG. 2b. The arrangement of the solar cell array 23 shown in FIG. 2b is typically used when the solar cells of the module are connected in series.

### Back-Sheet

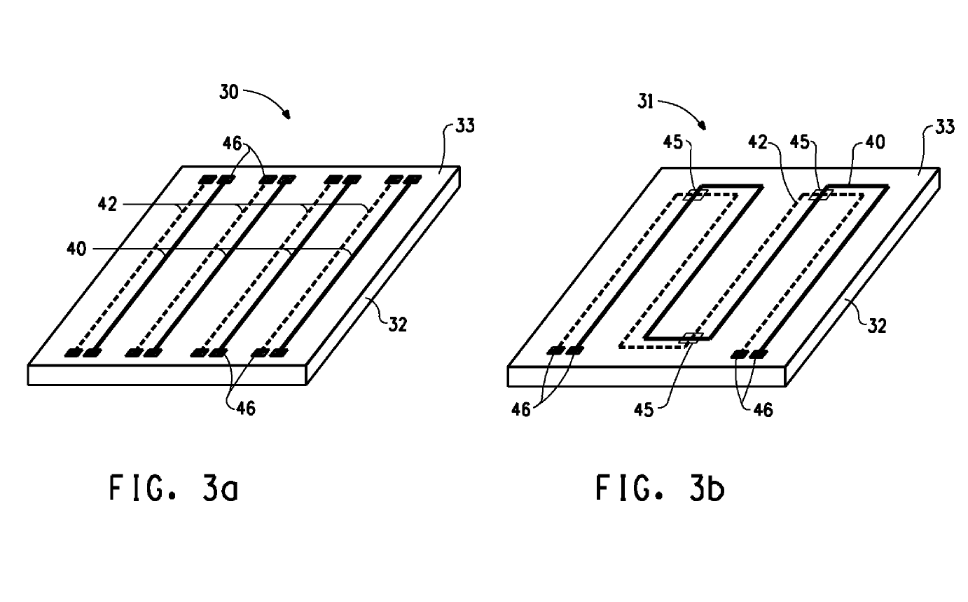

FIG. 3a shows an embodiment of the disclosed glass back sheet with integrated conductive circuitry. The back-sheet 30 shown in FIG. 3a is comprised of a rigid glass sheet 32. The glass sheet 32 has a surface 33 on which conductive circuitry is formed and an opposite side (not shown) that forms an exposed surface on the back of a photovoltaic module into which the back-sheet is incorporated. The back-sheet is preferably made of a strong shatter proof glass. Low lead galss is preferred for environmental reasons. The thickness of the glass depends in part on area of the module and the inherent strength of the glass material. For back-contact photovoltaic modules with typical areas of from 1 to 2 m², a back-sheet glass thickness of from 1.5 mm to 4 mm is preferred.

The glass sheet of the back-sheet has a coefficient of thermal expansion (CTE) that is closely matched to the CTE of the solar cells of the solar cell layer. Preferably the CTE of the glass back-sheet is within plus or minus 15% of the CTE of the solar cells, and more preferably within plus or minus 10% of the CTE of the solar cells. It has been found that selecting a glass sheet with a CTE that is closely matched to the CTE of the solar cells makes it possible to secure and maintain the electrical contacts between the solar cell back contacts and the conductive circuitry of the back-sheet for long periods of time. For example where the photovoltaic cells of the module are silicon based solar cells such as crystalline silicon solar cells, the glass of the back-sheet is selected so as to have a CTE that is closely matched to the CTE of the solar cells. Silicon has a CTE in the range of 2.5×10⁻⁶ to 3.2×10⁻⁶ so where the solar cells are silicon-based solar cells such as crystalline silicon solar cells, the back-sheet glass preferably has a CTE for from about 2×10⁻⁶ to 4×10⁻⁶ per degree C., and more preferably from about 2.3×10⁻⁶ to 3.7×10⁻⁶ per degree C.

As described below, the conductive circuitry is formed by printing a paste of a conductive metal and a glass frit in an organic medium on the glass sheet and then firing the paste at a peak firing temperature of from 550 to 750° C. Accordingly, the glass of the back-sheet should have a refractory temperature that can withstand such firing temperatures.

One preferred glass is an alkaline-earth aluminosilicate glass with a reported CTE of 3.5×10⁻⁶ and a density of 2.56 g/cm³ that is sold by Corning Glass of Corning, N.Y. under Corning Code 1729. Another glass with a lower refractory temperature but that also has a CTE closely matched to silicon is a soda borosilicate glass with a reported CTE of 3.25×10⁻⁶ and a density of 2.23 g/cm³ that is sold by Corning Glass under Corning Code 7740.

The glass back-sheet has conductive circuitry formed on the surface of the glass sheet that will face the solar cells. As shown in FIGS. 3a and 3b, conductive circuits 40 and 42 are formed on the glass sheets. The conductive circuits are fired from a metal and glass filled paste applied to the glass so as to form sintered conductive lines on the surface 33 of the glass sheet 32. The conductive circuits may be applied by printing paste-like solid-liquid dispersions of finely divided particles of metal and an inorganic binder such as glass frit in an organic medium.

The metal particles of the paste-like dispersion are typically silver, gold, platinum, palladium, aluminum or mixtures or alloys thereof. Where the paste is fired in a very low oxygen environment, such as a nitrogen atmosphere, the metal particles may comprise base metal particles such as copper, nickel or alloys thereof. The size of the metal powder or flake is not critical for effectiveness, but particle size does affect the sintering characteristics in that large particles sinter at a slower rate than smaller particles. Blends of powders and/or flakes of differing sizes can be used to tailor the sintering characteristics during firing. The metal particles must be of a size appropriate to the method of application. Where the paste-like dispersion is applied by screen printing to the glass, the particles should have an average diameter no larger than 20 microns and preferably no larger than 10 microns. Normally the minimum average particle diameter is about 0.1 microns.

The inorganic binder is preferably comprised of finely divided particles of inorganic glass frit compositions. The glass frit bonds the sintered metal particles to each other and to the glass. The softening point, viscosity and wetting characteristics of the frit are important for the performance of the conductive metal and to the adhesion of the conductive metal circuitry to the glass sheet. The glass frit may be a lead silicate, but due to environmental considerations, lead-free glass frits such as zinc or bismuth borosilicates may be employed. The glass frit typically comprises from about 1 to 20% by weight of the conductive metal composition. The glass frit typically has an average particle size of about 0.5 to about 5 microns.

The organic medium can be any suitable inert liquid that provides appropriate wettability of the metal and glass frit solids and the glass sheet, a relatively stable dispersion of particles, good screen printing performance with acceptable printing screen life, and good firing properties. The organic medium typically constitutes from 5 to 50% by weight of the paste. Organic liquids that can be used are alcohols, esters of such alcohols, terpenes such as pine oil, terpineol, and solutions of resins such as polymethacrylate, polyvinylpyrrolidone or ethyl cellulose in solvents such as pine oil and monobutyl ether or diethylene glycol monoacetate. A preferred orgainic medium is based on a combination of a thickener consisting of ethyl cellulose in terpineol (ratio of 1 to 9) combined with the monobutyl ether or ethylene glycol monoacetate sold under the tradename butyl Carbitol acetate.

The conductive paste-like composition can be prepared in a three-roll mill. A preferred viscosity is approximately 30-100 Pa·S measured on a Brookfield HBT viscometer using a #5 spindle at 10 rpm and 25° C. The amount of thickener utilized is determined by the final desired formulation viscosity, which in turn, is determined by the printing requirements. Conductive paste-like compositions suitable for making the back-contact integrated glass back-sheet and suitable processes for firing such composition on glass substrates are described in U.S. Pat. No. 5,378,408 and U.S. Patent Publication No. US2004/0104262 A1, which are hereby incorporated by reference.

The conductive paste-like composition described above is used to form the conductive lines on the surface of the glass back-sheet. The paste-like composition can be printed on the glass by screen printing or by other application means used in the electronics industry. The paste-like composition is printed with a thickness of about 20 to 30 microns and a width of anywhere from 2 to 20 times the thickness. A wider conductive line makes it easier to physically and electrically connect the solar cell back contacts to the conductive circuitry. The glass back-sheet with the metal and glass paste is then fired (also known as annealing) in a firing furnace at peak firing temperature of from about 550 to 750° C., and more preferably from 600 to 700° C. The fired conductive circuitry typically has a thickness of from 10 to 25 microns. The desired width and thickness of the conductive circuit lines depends, in part, on the electric current carrying requirements of the solar cells and the photovoltaic module. Where the current carrying capacity is high, the sintered metal conductive lines can be plated with copper, nickel or another conductive metal so as to increase conductance. Typically, each solar cell generates about 9 amps at 0.5 volts.

As shown in FIG. 3a the conductive circuits 40 and 42 may be formed as straight lines on the surface of the glass substrate 32. Where the conductive circuit lines will be positioned over solar cell back contact that are all arranged in the same orientation, as shown in FIG. 2a, one set of lines 42 connects to the negative polarity contacts on the backs of the solar cells and another set of lines 40 connects to the positive polarity contact on the back of a column of solar cells so as to connect the solar cell column in parallel. Where the conductive circuit lines will be positioned over solar cell back contact that are all arranged in the alternating orientation as shown in FIG. 2b, both sets of conductive lines 42 and 40 alternately connect to the positive and negative polarity contacts of solar cells so as to connect a column of cells in series. When the solar cells are connected in series, the conductive circuit lines may be printed in a manner such that there is a break in one of the conductive circuit lines 40 and 42 between every other cell in a line of series connected solar cells. Conductive pads 46 are formed at the ends of the conductive lines. The conductive pads may be formed from and fired from the paste-like material used to form the conductive lines by a similar screen printing and firing process. The pads may be connected by a ribbon wires to a junction box of a module or to conductive lines on another module.

FIG. 3b shows an alternative arrangement of the conductive lines in which a more complex circuit pattern is printed on the glass substrate. Where the conductive lines cross each other, glass insulating layers or other dielectric insulating layers are formed between the conductive lines at the point of cross over. Insulating cross over pads 45 are shown in FIG. 3b at the cross over points of the conductive lines. The insulating pads 45 may have a width or diameter of around 5 mm and a thickness sufficient to provide the necessary electrical insulation between the crossing conductive circuit lines.

### Interlayer Dielectric Layer

In order to prevent electrical shorting of the solar cells, it may be necessary to apply an electrically insulating dielectric material between the conductive circuitry on the integrated back-sheet and the back of the solar cells of the back-contact solar cell array. This dielectric layer is provided to maintain a sufficient electrical separation between the conductive circuit and the back of the solar cells. The dielectric layer, known as an interlayer dielectric (ILD), may be applied as a sheet over all of conductive circuit on the integrated back-sheet. It is necessary to form openings in the ILD as for example by die cutting or punching sections of the ILD, that will be aligned over the back contacts of the solar cells and through which the back contacts will be electrically connected to the conductive circuit lines on the back-sheet. Alternatively, the ILD may be applied by screen printing. The ILD can be printed on the back of the solar cells or on the glass back-sheet over the integrated circuitry. The ILD can cover the entire area between the glass back-sheet and the solar cell array or just selected areas where the conductive circuitry is present on the back-sheet. Where the ILD is printed, it may be printed only in the areas where the conductive circuit needs to be prevented from contacting the back of the solar cells. The ILD is applied to the back-sheet or to the back of the solar cell array before back sheet is applied to the back of the solar cell array. Where the ILD is a preformed sheet, it may cover the entire back-sheet or the ILD may be applied as strips of sheet material over the conductive lines on the glass back-sheet or as strips over the portions of the back side of the solar cells over which the conductive lines on the glass back-sheet will be positioned.

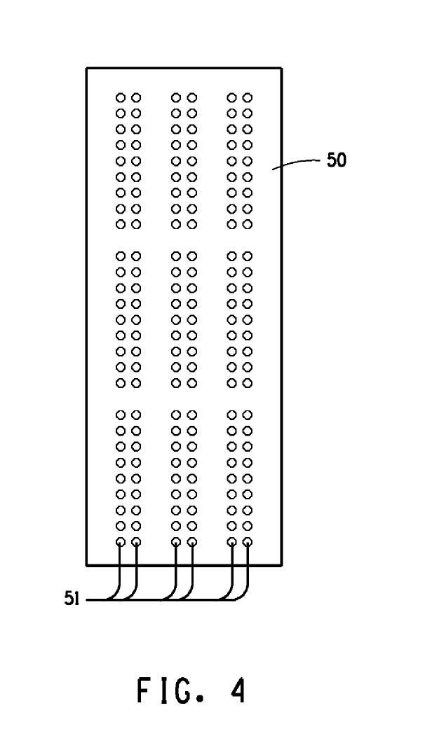

The thickness of the ILD will depend in part on the insulating properties of the material comprising the ILD, but preferred polymeric ILDs have a thickness in the range of 5 to 500 microns, and more preferably 10 to 300 microns and most preferably 25 to 200 microns. An example of an ILD layer is shown in FIG. 4. The ILD may be in the form of a sheet that covers at least one column of solar cells in the solar cell array, and is preferably in a form that covers multiple columns of solar cells in the solar cell array, or more preferably covers all of the columns of solar cells in the solar cell array. Openings 52 are formed in the ILD. These openings will correspond to the arrangement of the solar cell back contacts when the ILD is positioned between the conductive circuitry of the glass back-sheet and the back of the solar cell array. Preferably, the openings are formed by punching or die cutting the ILD, but alternatively the ILD can be formed with the openings.

The ILD may be comprised of an insulating material such as a thermoplastic or thermoset polymer. Preferably the ILD is comprised of a material that can be die cut or punched, or that can be printed or otherwise formed with openings in it. For example, the ILD may be an insulating polymer film such as a polyester, polyethylene or polypropylene film. Examples of other insulating layers useful in the ILD may include layers, films or sheets comprising poly(vinyl butyral)(PVB), ethylene vinyl acetate (EVA), poly(vinyl acetal), polyurethane (PU), linear low density polyolefins such as polyethylene, polyolefin block elastomers, ethylene acrylate ester copolymers, silicone polymers and epoxy resins. In one embodiment, the ILD is comprised of a PET polymer film that is coated with or laminated to an adhesive or an encapsulant layer such as an EVA film.

The ILD may be coated with an adhesive, such as a pressure sensitive adhesive, on the side of the ILD that will initially be contacted with the glass back-sheet. Suitable adhesive coatings on the ILD include pressure sensitive adhesives, thermoplastic or thermoset adhesives such as the ethylene copolymer acrylic, epoxy, vinyl butryal, polyurethane, or silicone adhesives.

### Encapsulant Material

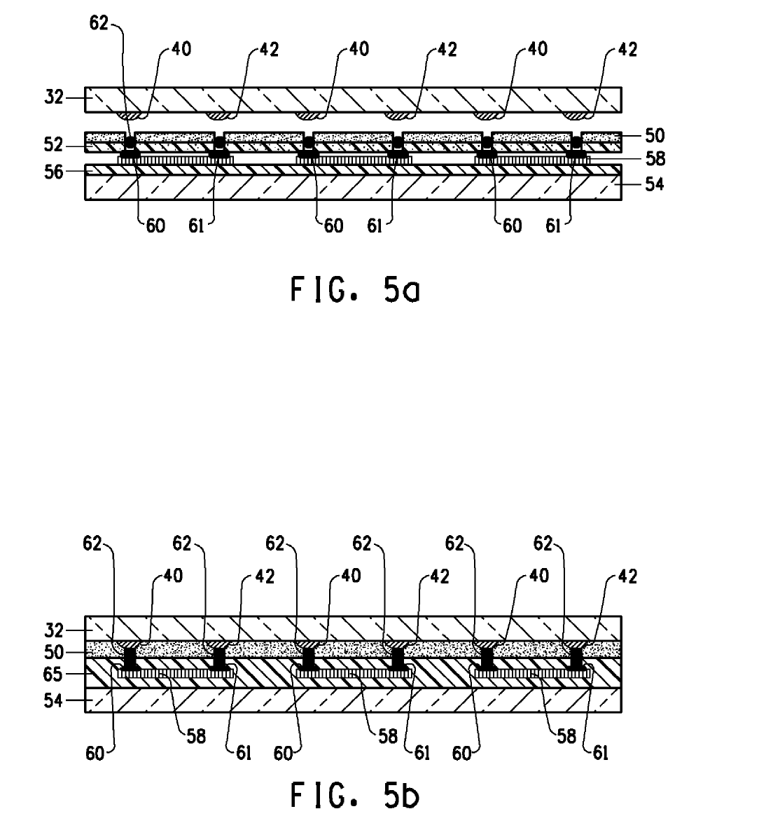

As shown in FIG. 5a, encapsulant layers 52 and 56 are provided on opposite side of the solar cell layer 58. The encapsulant layers are used to encase the fragile voltage-generating solar cell layer 58 so as to protect it from environmental or physical damage and hold it in place in the photovoltaic module. Suitable polymer materials for these encapsulant layers typically possess a combination of characteristics such as high impact resistance, high penetration resistance, high moisture resistance, good ultraviolet (UV) light resistance, good long term thermal stability, adequate adhesion strength to front sheets, back-sheets, other rigid polymeric sheets and cell surfaces, and good long term weatherability.

Encapsulant materials may include ethylene methacrylic acid and ethylene acrylic acid, ionomers derived therefrom, or combinations thereof. Such encapsulant layers may also be films or sheets comprising poly(vinyl butyral)(PVB), ionomers, ethylene vinyl acetate (EVA), poly(vinyl acetal), polyurethane (PU), polyolefins such as polyethylene, polyolefin block elastomers, ethylene acrylate ester copolymers, such as poly(ethylene-co-methyl acrylate) and poly(ethylene-co-butyl acrylate). As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic Table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn Ionomer Resins”, Polyelectrolytes, 1976, C, 177-197. Other suitable ionomers are further described in European patent EP1781735, which is herein incorporated by reference.

Ethylene copolymers that may be used for adhesive and encapsulant layers are more fully disclosed in PCT Patent Publication No. WO2011/044417 which is hereby incorporated by reference. Such ethylene copolymers are comprised of ethylene and one or more monomers selected from the group of consisting of C1-4 alkyl acrylates, C1-4 alkyl methacrylates, methacrylic acid, acrylic acid, glycidyl methacrylate, maleic anhydride and copolymerized units of ethylene and a comonomer selected from the group consisting of C4-C8 unsaturated anhydrides, monoesters of C4-C8 unsaturated acids having at least two carboxylic acid groups, diesters of C4-C8 unsaturated acids having at least two carboxylic acid groups and mixtures of such copolymers, wherein the ethylene content in the ethylene copolymer preferably accounts for 60-90% by weight. A preferred ethylene copolymer adhesive layer includes a copolymer of ethylene and another α-olefin. The ethylene content in the copolymer accounts for 60-90% by weight, preferably accounting for 65-88% by weight, and ideally accounting for 70-85% by weight of the ethylene copolymer. The other comonomer(s) preferably constitute 10-40% by weight, preferably accounting for 12-35% by weight, and ideally accounting for 15-30% by weight of the ethylene copolymer. The ethylene copolymer adhesive layer is preferably comprised of at least 70 weight percent of the ethylene copolymer. The ethylene copolymer may be blended with up to 30% by weight, based on the weight of the adhesive layer, of other thermoplastic polymers such as polyolefins, as for example linear low density polyethylene, in order to obtain desired properties. Ethylene copolymers are commercially available, and may, for example, be obtained from DuPont under the trade-name Bynel®.

The encapsulant layers may further contain any additive, filler or reinforcing agent known within the art. Such exemplary additives include, but are not limited to, plasticizers, processing aides, flow enhancing additives, lubricants, pigments, titanium dioxide, calcium carbonate, dyes, flame retardants, impact modifiers, nucleating agents to increase crystallinity, antiblocking agents such as silica, thermal stabilizers, hindered amine light stabilizers (HALS), UV absorbers, UV stabilizers, anti-hydrolytic agents, dispersants, surfactants, chelating agents, coupling agents, adhesives, primers, reinforcement additives, such as glass fiber, and the like. There are no specific restrictions to the content of the additives, fillers and reinforcing agents in the encapsulant layers as long as they do not produce an adverse impact on the adhesion properties or stability of the layer.

### Module Assembly

FIGS. 5a and 5b illustrate in cross section the steps of one process for making a back-contact solar module with the disclosed integrated glass back-sheet. As shown in FIG. 5a, a transparent front sheet 54, made of glass or a polymer such as a durable fluoropolymer, is provided. Where the back-sheet is a rigid glass substrate, as disclosed herein, the front sheet may be comprised of a transparent, lightweight and flexible sheet or film, such as a polymer sheet. Where moisture ingress is a very high priority, as for example with CIGS solar cells, it may be desirable for both the front and back sheets of the module to be glass sheets. For modules with silicon-based solar cells and the disclosed glass back-sheet, the light-transmitting layer 54 is preferably comprised of durable polymer sheet or film, such as, polycarbonate, acrylic, polyacrylate, cyclic polyolefin, such as ethylene norbornene polymer, polystyrene, polyamide, polyester, fluoropolymers and the like and combinations thereof. Preferred fluoropolymer front sheets are comprised of polyvinylfluoride, polyvinylidene fluoride, polytetrafluoroethylene, ethylene-tetrafluoroethylene copolymer, and tetrafluoroethylene-hexafluoropropylene copolymer.

A front encapsulant layer 56 may be applied over the front sheet 54. The encapsulant may be comprised of any of the encapsulant or adhesive materials described above. The front encapsulant layer typically has a thickness of from 200 to 500 microns.

Photoactive solar cells of the solar cell layer 58, such as a crystalline silicon solar cells, are provided on the front encapsulant layer 56. The solar cells have all of their electrical contacts on the back side. The best known types of back-contact solar cells are metal wrap through (MWT), metal wrap around (MWA), emitter wrap through (EWT), emitter wrap around (EWA), and interdigitated back contact (IBC). Electrical conductors on the light receiving front side of the solar cell (facing the transparent front sheet) are connected through vias (not shown) in the solar cell to back side conductive pads 60, while a back side conductive layer (not shown) is electrically connected to back side contact pads 61. The back contact pads are typically silver pads fired on the solar cells from a conductive paste of silver particles and glass frit in an organic carrier medium.

The back encapsulant layer 52 is placed on the back of the back contact solar cells. Holes, spaces or vias formed in the back encapsulant layer are aligned over the back contacts 60 and 61 of the solar cells 58. An ILD 50 is placed over the back encapsulant layer 52. The ILD also has holes, spaces or vias arranged to align over the back contacts 60 and 61 on the back side of the solar cells. The ILD layer may optionally have a pressure senstitive adhesive applied to the side of the ILD that faces the solar cells so that the ILD adheres to the back encapsulant layer. Alternatively, the ILD and the back encapsulant layer, may in some circumstances, be combined into a single layer of a thermoformable polymer material.

A small portion of a polymeric electrically conductive adhesive or a low melting temperature solder is provided over each of the contact pads 60 and 61. The portions of conductive adhesive or solder are shown as balls 62 in FIG. 5a. When a conductive adhesive is used to attach and electrically connect the conductive circuit lines 40 and 42 on the back-sheet to the back contacts of the solar cells, the conductive adhesive can be selected to have a softening temperature close to the temperature that must be applied to solar module during module lamination. During lamination, the adhesive polymer electrically connects and bonds the solar cell back contacts and the conductive lines on the glass back-sheet. Where solder is used to attach the solar cell back contacts to the conductive circuitry, the solder is preferably a low melting point solder, such as low melting point indium/tin solder alloy with a melting temperature of about 118° C., a tin/bismuth solder alloy with a melting temperature of about 139° C., an indium/silver alloy with a melting temperature of about 143° C., or other low melting temperature solder alloys containing indium with melting temperatures of around 160° C. or less. Where conductive adhesive is used to attach the solar cell back contacts to the conductive circuitry, the conductive adhesive may be any known conductive adhesive, such as an adhesive comprised of conductive metal particles, such as silver, nickel, conductive metal coated particles or conductive carbon suspended in epoxies, acrylics, vinyl butryals, silicones or polyurathanes. Preferred conductive adhesives are aniostropically conductive or z-axis conductive adhesives that are commonly used for electronic interconnections.

FIG. 5b shows a cross section of the disclosed photovoltaic module after thermal lamination of the module. During thermal lamination of the module, the encapsulant layers 52 and 56 melt and then form the cured encapsulant layer 65 that can be seen in FIG. 5b between the front sheet 54 and the ILD layer 50. The ILD layer is adhered to the glass back-sheet 32 during the module lay-up and lamination.

The photovoltaic module of FIG. 5b may be laminated through autoclave and non-autoclave processes. For example, the photovoltaic module construct described with regard to FIG. 5a may be laid up in a vacuum lamination press and laminated together under vacuum with heat and standard atmospheric or elevated pressure. In an exemplary process, a polymeric front sheet, a front-sheet encapsulant layer, a back-contact photovoltaic cell layer, a back encapsulant layer, an ILD, and a rigid glass back-sheet with patterned conductive circuitry on a surface thereof are laminated together under heat and pressure and a vacuum (for example, in the range of about 27-28 inches (689-711 mm) Hg) to remove air. In an exemplary procedure, the laminate assembly is placed into a bag capable of sustaining a vacuum (“a vacuum bag”), drawing the air out of the bag using a vacuum line or other means of pulling a vacuum on the bag, sealing the bag while maintaining the vacuum, placing the sealed bag in an autoclave at a temperature of about 130° C. to about 180° C., at a pressure of from 50 to 250 psig, and preferably about 200 psi (about 14.3 bars), for from about 10 to about 50 minutes. Preferably the bag is autoclaved at a temperature of from about 140° C. to about 160° C. for about 20 minutes to about 35 minutes. More preferably the bag is autoclaved at a temperature of about 150° C. for about 20 minutes to about 30 minutes.

Air trapped within the laminate assembly may be removed using a nip roll process. For example, the laminate assembly may be heated in an oven at a temperature of about 80° C. to about 120° C., or preferably, at a temperature of between about 90° C. and about 100° C., for about 30 minutes. Thereafter, the heated laminate assembly is passed through a set of nip rolls so that the air in the void spaces between the photovoltaic module outside layers, the photovoltaic cell layer and the encapsulant layers may be squeezed out, and the edge of the assembly sealed. This process may provide a final photovoltaic module laminate or may provide what is referred to as a pre-press assembly, depending on the materials of construction and the exact conditions utilized.

The pre-press assembly may then be placed in an air autoclave where the temperature is raised to about 120° C. to about 160° C., or preferably, between about 135° C. and about 160° C., and the pressure is raised to between about 50 psig and about 300 psig, or preferably, about 200 psig (14.3 bar). These conditions are maintained for about 15 minutes to about 1 hour, or preferably, about 20 to about 50 minutes, after which, the air is cooled while no more air is added to the autoclave. After about 20 minutes of cooling, the excess air pressure is vented and the photovoltaic module laminates are removed from the autoclave. The described process should not be considered limiting. Essentially, any type of lamination process known within the art may be used to produce the back contact photovoltaic modules with a rigid glass back-sheet and back circuitry as disclosed herein.

If desired, the edges of the photovoltaic module may be sealed to reduce moisture and air intrusion by any means known within the art. Such moisture and air intrusion may degrade the efficiency and lifetime of the photovoltaic module. Edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

While the presently disclosed invention has been illustrated and described with reference to preferred embodiments thereof, it will be appreciated by those skilled in the art that various changes and modifications can be made without departing from the scope of the present invention as defined in the appended claims.

What is claimed is:

1. A photovoltaic module, comprising:
a solar cell array of at least four solar cells, each of said solar cells in said array having a front light receiving side and an opposite back side, the back side of each of said solar cells having positive and negative polarity electrical contacts thereon, the solar cells of said solar cell array having a substantially common coefficient of thermal expansion;
a glass back-sheet having a first surface facing the back side of the solar cells of said solar cell array and an opposite second surface, the glass back sheet having a coefficient of thermal expansion that is within 15% of the coefficient of thermal expansion of the solar cells of the solar cell array, said glass back-sheet having at least two conductive circuits on the first surface of the glass back-sheet, the conductive circuits being comprised of sintered metal and an inorganic binder, wherein said conductive circuits are physically and electrically connected to the electrical contacts on the back side of the solar cells of the solar cell array.

2. The photovoltaic module of claim 1 wherein the solar cells of the solar cell array are silicon-based solar cells, and wherein the glass back sheet has a coefficient of thermal expansion in the range of 2×10⁻⁶ to 4×10⁻⁶ per degree C.

3. The photovoltaic module of claim 2 wherein the solar cells of the solar cell array are solar cells selected from crystalline silicon solar cells, polycrystalline silicon solar cells, microcrystalline silicon solar cells, and amorphous silicon-based solar cells.

4. The photovoltaic module of claim 3 whering the solar cells of the solar cell array are each single crystal silicon solar cells.

5. The photovoltaic module of claim 1 wherein the glass back-sheet has a thickness of at least 1.5 mm, and is comprised of glass selected from aluminosilicate glass and borosilicate glass.

6. The photovoltaic module of claim 1 wherein the at least two conductive circuits on the first surface of the glass back-sheet are comprised of metal selected from silver, gold, platinum, palladium, aluminum or mixtures or alloys thereof, and wherein the inorganic binder is glass.

7. The photovoltaic module of claim 6 wherein in the at least two conductive circuits the glass binder comprises from about 1 to 20% by weight of the metal.

8. The photovoltaic module of claim 6 wherein the glass binder is comprised of lead silicate, zinc borosilicate, bismuth borosilicate, and combinations thereof.

9. The photovoltaic module of claim 1 wherein the second surface of the glass back-sheet forms and exterior exposed surface of the photovoltaic module.

10. The photovoltaic module of claim 1 wherein the solar cells of the solar cell array are silicon-based solar cells, and wherein the glass back sheet has a coefficient of thermal expansion that is within 10% of the coefficient of thermal expansion of the solar cells of the solar cell array.

11. The photovoltaic module of claim 1 further comprising a transparent polymeric front sheet on the front light receiving side of the solar cells of the solar cell array.

12. The photovoltaic module of claim 1 wherein the front sheet comprises a fluoropolymer film comprised of polyvinylfluoride, polyvinylidene fluoride, polytetrafluoroethylene, ethylene-tetrafluoroethylene copolymer, and tetrafluoroethylene-hexafluoropropylene copolymer.

13. The photovoltaic module of claim 1 further comprising a back encapsulant layer between the glass back sheet and the back side of the solar cells of the array of solar cells, wherein said encapsulant layer has openings aligned with the electrical contacts on the back side of the array of solar cells.

14. The photovoltaic module of claim 1 further comprising an interlayer dielectric layer between the glass back sheet and the back side of the solar cells of the array of solar cells, wherein said interlayer dielectric layer has openings aligned with the electrical contacts on the back side of the array of solar cells.

15. The photovoltaic module of claim 14 wherein the interlayer dielectric layer is a screen printed layer printed on one of the first side of the glass back-sheet or on the back side of the solar cells of the array of solar cells.

16. The photovoltaic module of one of claim 13 wherein the said conductive circuits on the first side of the glass back-sheet are physically and electrically connected to the electrical contacts on the back side of the solar cells of the solar cell array by a conductive solder or a conductive polymeric adhesive.

17. The photovoltaic module of one of claim 14 wherein the said conductive circuits on the first side of the glass back-sheet are physically and electrically connected to the electrical contacts on the back side of the solar cells of the solar cell array by a conductive solder or a conductive polymeric adhesive passing through the openings in the interlayer dielectric layer.

18. A process for making a back-contact photovoltaic module comprising:
providing a solar cell array of at least four solar cells, each of said solar cells in said array having a front light receiving side and an opposite back side, the back side of each of said solar cells having positive and negative polarity electrical contacts thereon, the solar cells of said solar cell array having a substantially common coefficient of thermal expansion;
providing a glass back-sheet having a first surface and an opposite second surface, the glass back sheet having a coefficient of thermal expansion that is within 15% of the coefficient of thermal expansion of the solar cells of the solar cell array;
forming at least two conductive circuits on the first surface of the glass back-sheet by
depositing a paste-like mixture of conductive metal particles and a glass frit particles in an organic carrier medium in at least two circuit patterns on the first surface of the glass back-sheet, and
firing the glass back-sheet and deposited paste-like mixture at a peak firing temperature in the range of 550° C. to 750° C. to form patterned conductive circuits of sintered metal and glass binder on the first surface of the glass back-sheet;
physically and electrically connecting the electrical contacts on the back side of the solar cells of the solar cell array to the patterned conductive circuits on the first surface of the glass back-sheet.

19. The process of claim 18, further comprising the step of providing a front encapsulant layer on the front light receiving side of the solar cells and a back encapsulant layer between the glass back sheet and the back side of the solar cells of the array of solar cells, wherein said back encapsulant layer has openings aligned with the electrical contacts on the back side of the array of solar cells.

20. The process of claim 19, further comprising the step of providing a front sheet on a side of the front encapsulant layer opposite the solar cells, wherein the front sheet comprises a polymer film.
